(19) United States
(12) Patent Application Publication
(10) Pub. No.: US 2025/0046575 A1
(43) Pub. Date: Feb. 6, 2025

(54) Plasma Processing Device

(71) Applicant: Tokyo Electron Limited, Tokyo (JP)

(72) Inventor: Takahiro SHINDO, Tokyo (JP)

(21) Appl. No.: 18/927,757

(22) Filed: Oct. 25, 2024

Related U.S. Application Data
(63) Continuation of application No. PCT/JP2023/016739, filed on Apr. 27, 2023.

(30) Foreign Application Priority Data
May 10, 2022 (JP) 2022-077386

(51) Int. Cl. H01J 37/32

(52) U.S. Cl. CPC H01J 37/32174; H01J 37/32541; H01J 37/32568

(57) ABSTRACT

A plasma processing apparatus comprises a plasma supply part including an upper electrode being electrically connected to a RF power supply and to which an RF voltage from the RF power supply is applied, and a lower electrode part being disposed to face the upper electrode, a gas supply part configured to supply to the plasma supply part a processing gas, and a voltage adjusting part used for adjusting a voltage of the upper electrode. The lower electrode part includes an electrode plate having a mesh structure and configured to allow communication between an inner region and an outer region of the plasma supply part provided by the lower electrode part. The plasma supply part and the voltage adjusting part are configured to lower a sheath voltage of a sheath region formed on the lower electrode part during plasma generation in the plasma supply part.

### CROSS-REFERENCE TO RELATED APPLICATIONS

This application is a bypass continuation application of International Application No. PCT/JP2023/016739 having an international filing date of Apr. 27, 2023 and designating the United States, the International Application being based upon and claiming the benefit of priority from the Japanese Patent Application No. 2022-077386 filed on May 10, 2022, the entire contents of which are incorporated herein by reference.

### TECHNICAL FIELD

An exemplary embodiment of the present disclosure relates to a plasma processing apparatus.

### BACKGROUND

Plasma processing is often used as processing for a substrate such as a semiconductor wafer. A plasma processing apparatus is used for plasma processing, and plasma can be provided by, e.g., a remote plasma source. Japanese Laid-open Patent Publication No. 2020-155387, Japanese Laid-open Patent Publication No. 2008-172168, Japanese Laid-open Patent Publication No. 2007-103944, and Japanese Laid-open Patent Publication No. 2022-018062 disclose techniques related to a plasma processing apparatus having a remote plasma source.

### SUMMARY

The present disclosure provides a technique for reducing influence of a remote plasma source on plasma.

In an exemplary embodiment, a plasma processing apparatus is provided. The plasma processing apparatus may include a processing chamber, a radio-frequency (RF) power supply, a plasma supply part, a gas supply part and a voltage adjusting part. The plasma supply part may include an upper electrode and a lower electrode part and be configured to supply only radicals, or radicals and some ions, to the processing chamber. The upper electrode may be electrically connected to the RF power supply and to which an RF voltage from the RF power supply may be applied. and the lower electrode part may be disposed to face the upper electrode. The gas supply part may be configured to supply to the plasma supply part a processing gas used for plasma generation in the plasma supply part. The voltage adjusting part may be used for adjusting a voltage of the upper electrode. The gas supply part may supply the processing gas to a space provided by the upper electrode and the lower electrode part. The lower electrode part may include an electrode plate having a mesh structure that extends along a surface of the upper electrode. The electrode plate having the mesh structure may be configured to allow communication between an inner region and an outer region of the plasma supply part provided by the lower electrode part. The plasma supply part and the voltage adjusting part may be configured to lower a sheath voltage of a sheath region formed on the lower electrode part during plasma generation in the plasma supply part.

### BRIEF DESCRIPTION OF THE DRAWINGS

FIG. 1 shows a plasma processing apparatus according to one exemplary embodiment.

FIG. 2 shows an example of a potential that may occur in an inner region of a plasma supply part of a plasma processing apparatus that does not include a voltage adjusting part shown in FIG. 1.

FIG. 3 shows an upper electrode potential that generates the potential shown in FIG. 2 that may occur in the inner region of the plasma supply part.

FIG. 4 shows an embodiment of the plasma supply part and the voltage adjusting part shown in FIG. 1.

FIG. 5 shows an embodiment of the plasma supply part and the voltage adjusting part shown in FIG. 1.

FIG. 6 shows an example of a potential that may occur in the inner region of the plasma supply part electrically connected to the voltage adjusting part shown in FIGS. 4 and 5.

FIG. 7 shows an upper electrode potential that generates the potential shown in FIG. 6 that may occur in the inner region of the plasma supply part.

FIG. 8 shows an embodiment of the plasma supply part and voltage adjusting part shown in FIG. 1.

FIG. 9 illustrates a filter circuit shown in FIG. 8.

FIG. 10 shows an example of a potential that may occur in the inner region of the plasma supply part electrically connected to the voltage adjusting part shown in FIG. 8.

FIG. 11 shows the potential of the upper electrode that generates the potential shown in FIG. 10 that may occur in the inner region of the plasma supply part.

FIG. 12 shows an embodiment of the plasma supply part and the voltage adjusting part shown in FIG. 1.

FIG. 13 shows an embodiment of the plasma supply part and the voltage adjusting part shown in FIG. 1.

FIG. 14 illustrates a potential that may occur in the inner region of the plasma supply part electrically connected to the voltage adjusting part shown in FIGS. 12 and 13.

FIG. 15 shows the potential of the upper electrode that generates the potential shown in FIG. 14 that may occur in the inner region of the plasma supply part.

FIG. 16 shows an embodiment of the plasma supply part and voltage adjusting part shown in FIG. 1.

### DETAILED DESCRIPTION

Various exemplary embodiments will be described below.

A plasma supply part that generates plasma and supplies only radicals or radicals and some ions to a process space is a remote plasma source is considered. In this case, the plasma is generated in an inner region of a plasma supply part 10, and processing is performed using only radicals or radicals and some ions in an outer region of the plasma supply part. A mesh structure that penetrates both regions and allows radicals in the plasma to pass therethrough may be used as a device for demarcating (dividing) the inner region and the outer region of the plasma supply part. Further, such a mesh structure may be used in a capacitively coupled plasma processing apparatus. In this case, the mesh may be damaged by collisions of ions in the plasma and heated, which may result in phenomenon that the mesh structure itself is damaged or particles generated by the damage leak to the outer region of the plasma supply part.

In an exemplary embodiment, a plasma processing apparatus is provided. The plasma processing apparatus may include a processing chamber, a radio-frequency (RF) power supply, a plasma supply part, a gas supply part and a voltage adjusting part. The plasma supply part may include an upper electrode and a lower electrode part and be configured to supply only radicals, or radicals and some ions, to the processing chamber. The upper electrode may be electrically connected to the RF power supply and to which an RF voltage from the RF power supply may be applied. and the lower electrode part may be disposed to face the upper electrode. The gas supply part may be configured to supply to the plasma supply part a processing gas used for plasma generation in the plasma supply part. The voltage adjusting part may be used for adjusting a voltage of the upper electrode. The gas supply part may supply the processing gas to a space provided by the upper electrode and the lower electrode part. The lower electrode part may include an electrode plate having a mesh structure that extends along a surface of the upper electrode. The electrode plate having the mesh structure may be configured to allow communication between an inner region and an outer region of the plasma supply part provided by the lower electrode part. The plasma supply part and the voltage adjusting part may be configured to lower a sheath voltage of a sheath region formed on the lower electrode part during plasma generation in the plasma supply part.

In this manner, the plasma supply part and the voltage adjusting part can reduce the sheath voltage of the sheath region formed on the lower electrode part including the electrode of the mesh structure during plasma generation. Therefore, damage to the lower electrode part and heating of the lower electrode part can be reduced, and the damage of the mesh structure itself or the phenomenon that particles generated by the damage leak to the outer region of the plasma supply part can be suppressed.

In an exemplary embodiment, the voltage adjusting part may include a diode. An anode of the diode may be electrically connected to the upper electrode. A cathode of the diode may be electrically connected to ground together with the lower electrode part.

In an exemplary embodiment, the voltage adjusting part may include a switch circuit. The lower electrode part may be electrically connected to ground. The switch circuit may be electrically connected between the lower electrode part and the upper electrode, and may be configured to suppress a positive voltage component of an RF voltage applied to the upper electrode by the RF power supply.

In an exemplary embodiment, the voltage adjusting part may include a diode, a filter circuit, and a DC power supply. An anode of the diode may be electrically connected to the upper electrode. The filter circuit may include a first capacitor, a second capacitor, a third capacitor, and an inductor. The inductor and the second capacitor may be electrically connected in parallel between the diode and the DC power supply. A cathode of the diode may be electrically connected to a negative terminal of the DC power supply via the inductor and the second capacitor. The cathode of the diode may be electrically connected to ground via the first capacitor. The negative terminal of the DC power supply may be electrically connected to the ground via the third capacitor. A positive terminal of the DC power supply may be electrically connected to the lower electrode part and the ground.

In an exemplary embodiment, the plasma processing apparatus may further comprise an electrode disposed on a sidewall of the plasma supply part extending between the upper electrode and the lower electrode part and electrically connected to ground. The voltage adjusting part may be configured to electrically connect the electrode to the ground. The lower electrode part may be configured to be in an electrically floating state.

In an exemplary embodiment, the plasma processing apparatus may further comprise an electrode disposed on a sidewall of the plasma supply part extending between the upper electrode and the lower electrode part and electrically connected to ground via an LC series resonant circuit. The voltage adjusting part may include the LC series resonant circuit. The lower electrode part may be configured to be in an electrically floating state.

In an exemplary embodiment, the plasma processing apparatus may further comprise an electrode disposed on a sidewall of a plasma supply part extending between the upper electrode and the lower electrode part and electrically connected to ground. The lower electrode part may include a first electrode plate and a second electrode plate, each having a mesh structure, extending parallel to each other. The first electrode plate may be disposed between the second electrode plate and the upper electrode and configured to be in an electrically floating state. The second electrode plate may be electrically connected to the ground. The voltage adjusting part may be configured to electrically connect the electrode and the second electrode plate to the ground.

Hereinafter, various exemplary embodiments will be described in detail with reference to the accompanying drawings. Further, like reference numerals will be used for like or corresponding parts throughout the drawings.

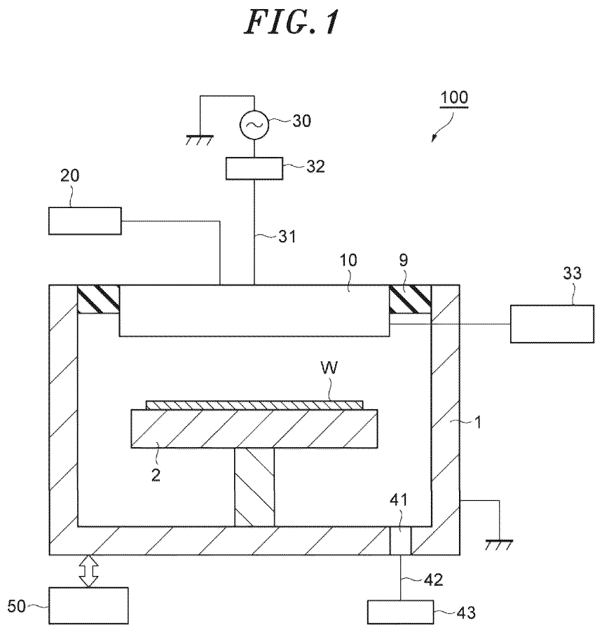

FIG. 1 is a cross-sectional view showing a plasma processing apparatus according to one exemplary embodiment. A plasma processing apparatus 100 performs radical processing on a process space including a substrate W, and is configured as a remote plasma processing apparatus using capacitively coupled plasma. The substrate W may be, e.g., a semiconductor wafer, but is not limited thereto.

The plasma processing apparatus 100 has a substantially cylindrical processing chamber 1 made of a metal. The processing chamber 1 is electrically connected to the ground (grounded). A substrate placing table 2 for horizontally placing the substrate W is disposed in the processing chamber 1.

The substrate placing table 2 may have a heating mechanism or a cooling mechanism depending on plasma processing. A plurality of lift pins (not shown) are inserted into the substrate placing table 2 to protrude beyond or retract below the upper surface thereof, and the substrate W is transferred to and from the substrate placing table 2 by raising or lowering the plurality of lift pins by a lifting mechanism (not shown).

The plasma processing apparatus 100 includes a gas supply part 20. The gas supply part 20 is configured to supply to the plasma supply part 10 a processing gas used for plasma generation in the plasma supply part 10.

The gas supply part 20 can supply a plurality of gases, such as a processing gas, a plasma generation gas, a purge gas, and the like required for plasma processing. An appropriate processing gas can be selected depending on the plasma processing to be performed. The gas supply part 20 has a plurality of gas supply sources and a plurality of gas supply lines, and each gas supply line is provided with a valve and a flow rate controller such as a mass flow controller.

An exhaust port 41 is disposed at a bottom wall of the processing chamber 1, and an exhaust device 43 is connected to the exhaust port 41 through an exhaust line 42. The exhaust device 43 includes an automatic pressure control valve and a vacuum pump, and is configured to exhaust the inside of the processing chamber 1 using the exhaust device 43 and to maintain the inside of the processing chamber 1 at a desired vacuum level.

The valves and the flow rate controller of the gas supply part 20, and individual components of the plasma processing apparatus 100, such as a radio-frequency (RF) power supply 30, can be controlled by a controller 50. The controller 50 may have a main controller having a CPU, an input device, an output device, a display device, and a storage device. The processing of the plasma processing apparatus 100 can be controlled based on a processing recipe stored in a storage medium of the storage device.

Further, although not shown, a loading/unloading port for loading/unloading the substrate W into/from the processing chamber 1 is provided at the sidewall of the processing chamber 1, and the loading/unloading port can be configured to be opened and closed by a gate valve.

An opening is formed at an upper part of the processing chamber 1, and the plasma supply part 10 is fitted into the opening via an insulating member 9 to face the substrate placing table 2. The plasma supply part 10 is configured to supply plasma to the processing chamber 1. The plasma supply part 10 includes an upper electrode 10a and a lower electrode part 10c.

The upper electrode 10a is electrically connected to the RF power supply and a radio-frequency (RF) voltage is applied from the RF power supply 30 to the upper electrode 10a. The lower electrode part 10c is disposed to face the upper electrode 10a. The RF power supply 30 can apply an RF voltage of 10 KHz to 60 MHz to the upper electrode 10a. A matching device 32 is connected to the RF power supply 30 on the downstream side of the power supply line 31. The matching device 32 matches a load impedance to an internal (or output) impedance of the RF power supply 30.

The lower electrode part 10c extends along the surface of the upper electrode 10a. The lower electrode part 10c includes an electrode plate 10c1. The electrode plate 10c1 has a mesh structure configured to allow communication between an inner region (region where plasma is generated) and an outer region (region where processing of the substrate W is performed by plasma) of the plasma supply part 10 provided by the lower electrode part 10c. The gas supply part 20 may supply a processing gas to the space provided by the upper electrode 10a and the lower electrode part 10c. The plasma supply part 10 is configured to generate plasma from the processing gas and supply electrically neutral radicals contained in the plasma into the processing chamber 1 through the lower electrode part 10c of the mesh structure.

Ions in the plasma generated in the plasma supply part 10 may be accelerated toward the lower electrode part 10c by a sheath voltage (the difference between the potential of the plasma and the potential of the lower electrode part 10c) of a sheath region MS on the lower electrode part 10c. The ions in the plasma may collide with the electrode plate of the mesh structure included in the lower electrode part 10c. Therefore, the lower electrode part 10c suppresses the supply of ions to the outer region of the plasma supply part 10 and supplies radicals in the plasma to the outer region of the plasma supply part 10 (may cause radicals to flow thereto) by the mesh structure.

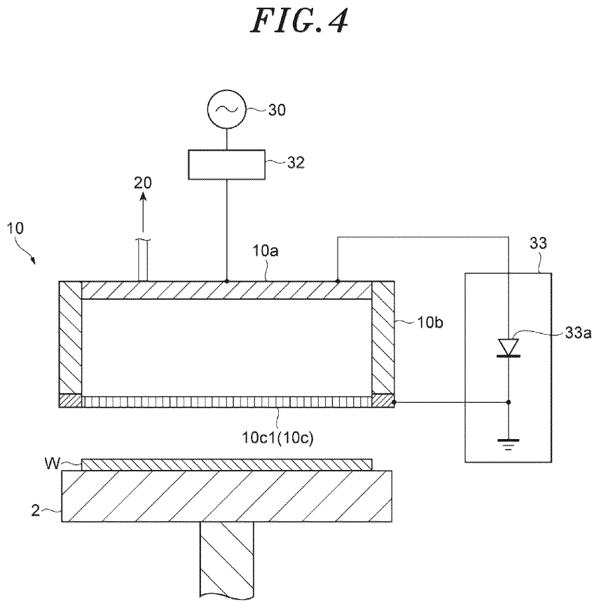

The plasma processing apparatus 100 includes a voltage adjusting part 33. The voltage adjusting part 33 is used for adjusting the voltage of the upper electrode 10a. The voltage adjusting part 33, or the plasma supply part 10 and the voltage adjusting part 33 (configurations shown in FIGS. 4, 5, 8, 12, 13, and 16) are configured to lower the voltage of the sheath region MS formed on the lower electrode part 10c during plasma generation in the plasma supply part 10. In this manner, the voltage adjusting part 33, or the voltage adjusting part 33 and the plasma supply part 10, can reduce the sheath voltage of the sheath region MS formed on the lower electrode part 10c including the electrode of the mesh structure during plasma generation. Therefore, damage to the lower electrode part 10c and heating of the lower electrode part 10c can be reduced, and the damage to the mesh structure itself or the phenomenon that particles generated by the damage leak to the outer region of the plasma supply part 10 can be suppressed. Further, although the case in which radicals are supplied from the plasma supply part 10 into the processing chamber 1 has been described, the plasma supply part may supply some of the ions in the plasma together with the radicals into the processing chamber 1 in order to improve the processing of the substrate W.

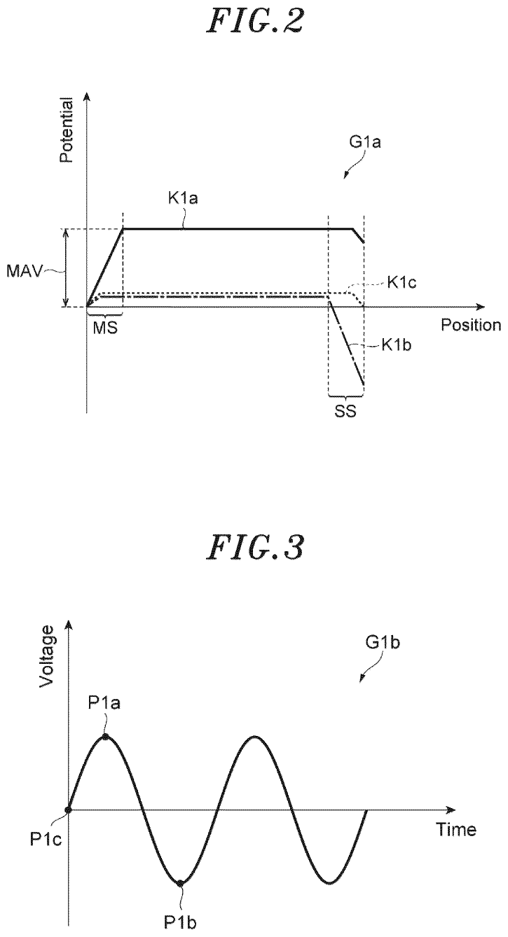

FIG. 2 illustrates a potential that may occur in the inner region of the plasma supply part 10 included in the plasma processing apparatus 100 that does not include the voltage adjusting part 33. FIG. 3 shows the potential of the upper electrode 10a that generates the potential shown in FIG. 2 that may occur in the inner region of the plasma supply part 10. With reference to FIGS. 2 and 3, in the plasma processing apparatus 100 that does not include the voltage adjusting part 33, the sheath voltage of the sheath region MS that may occur when an RF voltage with a waveform shown in a graph G1b is applied to the lower electrode part 10c by the RF power supply 30 is considered. In this case, an RF voltage is applied from the RF power supply 30 to the upper electrode 10a, and the lower electrode part 10c is electrically connected to ground.

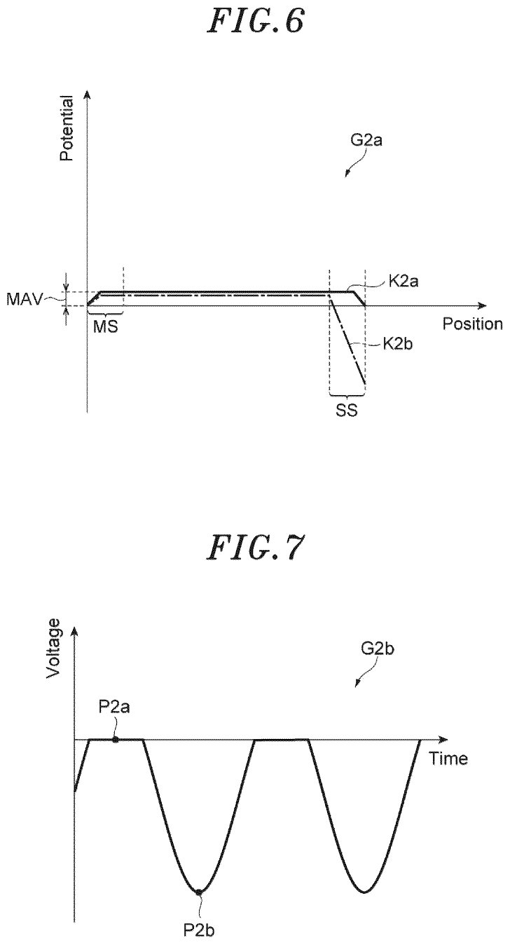

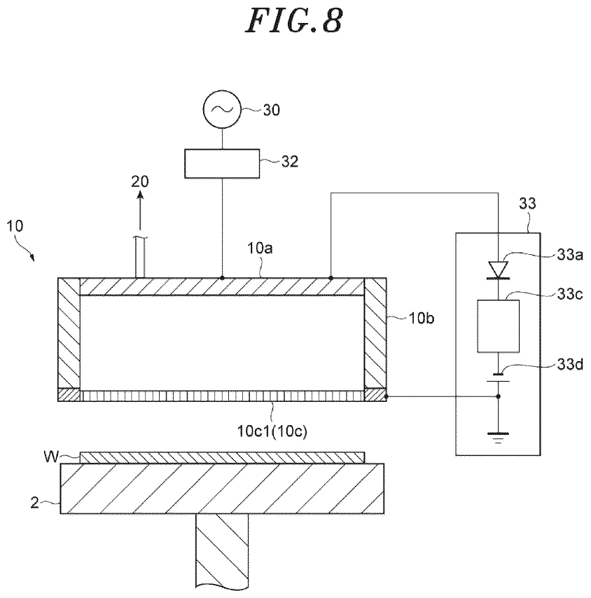

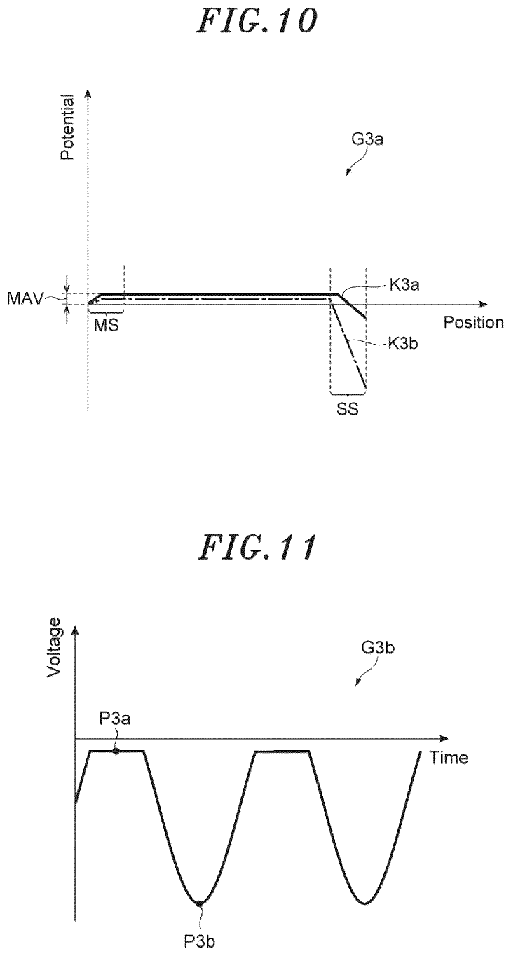

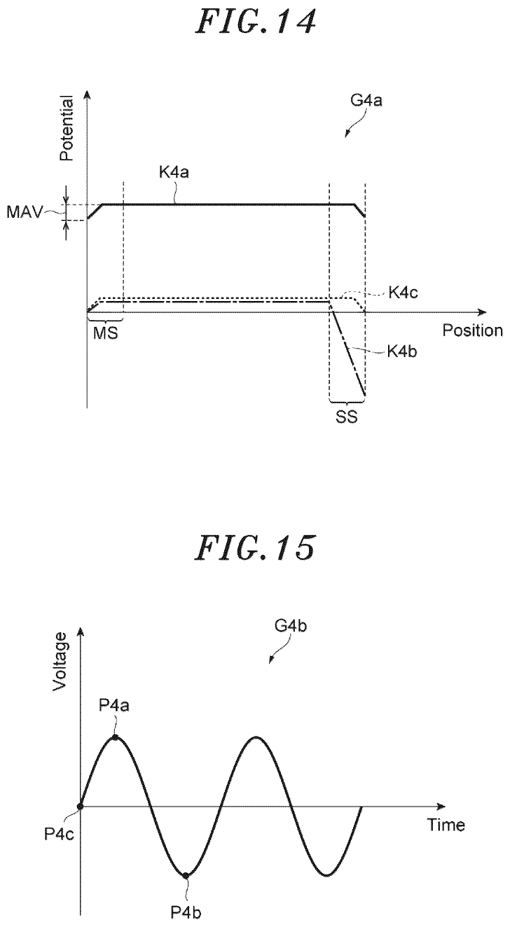

The horizontal axis of a graph G1a in FIG. 2 represents a position (referred to as “inner region of the plasma supply part 10”) of the space between the upper electrode 10a and the lower electrode part 10c. The left side of the horizontal axis corresponds to the lower electrode part 10c, and the right side of the horizontal axis corresponds to the upper electrode 10a. The vertical axis of the graph G1a represents a potential that may be generated in the inner region. The horizontal axis of the graph G1b in FIG. 3 represents time, and the vertical axis of the graph G1b represents a voltage of an RF voltage applied to the lower electrode part 10c. The horizontal axes and the vertical axes of a graph G2a in FIG. 6 and a graph G2b in FIG. 7 are the same as the horizontal axes and the vertical axes of the graph G1a in FIG. 2 and the graph G1b in FIG. 3. Further, the horizontal axes and the vertical axes of a graph G3a in FIG. 10 and a graph G3b in FIG. 11 are the same as the horizontal axes and the vertical axes of the graph G1a in FIG. 2 and the graph G1b in FIG. 3. Further, the horizontal axes and the vertical axes of a graph G4a in FIG. 14 and a graph G4b in FIG. 15 are the same as the horizontal axes and the vertical axes of the graph G1a in FIG. 2 and the graph G1b in FIG. 3. In the inner region of the plasma supply part 10, potentials expressed by broken lines K1a, K1b, and K1c shown in the graph G1a may occur. The broken line K1a represents the potential of the inner region of the plasma supply part 10 according to a positive peak (maximum value) of the RF voltage shown at a point P1a of the graph G1b that is applied to the upper electrode 10a. The broken line K1b of the graph G1b represents the potential of the inner region of the plasma supply part 10 corresponding to a negative peak (minimum value) of the RF voltage shown at a point P1b that is applied to the upper electrode 10a. The broken line K1c of the graph G1b represents the potential of the inner region of the plasma supply part 10 corresponding to a zero value of the RF voltage shown at a point P1c that is applied to the upper electrode 10a.

Among the potentials (the broken line K1a) that may be generated in the inner region corresponding to the positive peak (point P1a) of the RF voltage, the sheath voltage of the sheath region MS corresponds to a maximum acceleration voltage MAV of the ions in the plasma toward the lower electrode part 10c. A sheath region SS is formed below the upper electrode 10a in the inner region of the plasma supply part 10.

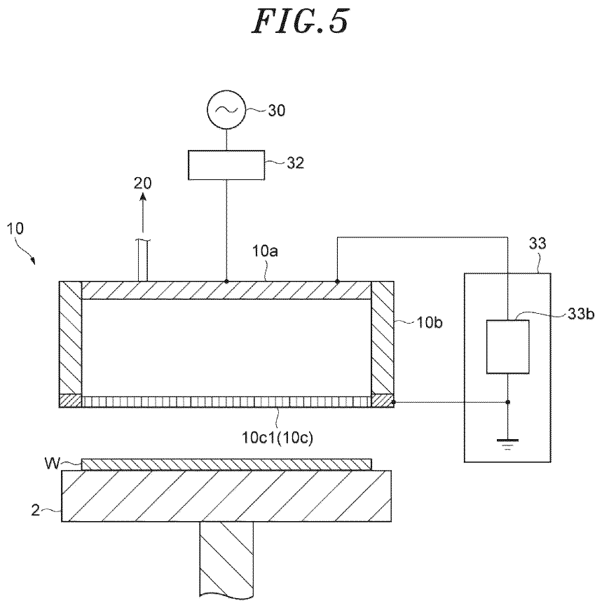

The plasma supply part 10 and the voltage adjusting part 33 of the plasma processing apparatus 100 according to one exemplary embodiment are shown in FIGS. 4 and 5.

The voltage adjusting part 33 shown in FIG. 4 is configured to suppress the positive voltage component of the RF voltage applied to the upper electrode 10a by the RF power supply 30. The voltage adjusting part 33 includes a diode 33a. The anode of the diode 33a is electrically connected to the upper electrode 10a. A cathode of the diode 33a is electrically connected to the ground together with the lower electrode part 10c.

The voltage adjusting part 33 shown in FIG. 5 is also configured to suppress the positive voltage component of the RF voltage applied to the upper electrode 10a by the RF power supply 30. The voltage adjusting part 33 shown in FIG. 5 includes a switch circuit 33b. The lower electrode part 10c shown in FIG. 5 is electrically connected to the ground. The switch circuit 33b is electrically connected between the lower electrode part 10c and the upper electrode 10a.

In the plasma processing apparatus 100 including the lower electrode part 10c and the voltage adjusting part 33 shown in FIG. 4 or 5, the maximum acceleration voltage MAV (sheath voltage of the sheath region MS) shown in the graph G2a of FIG. 6 is lower than the maximum acceleration voltage MAV shown in the graph G1a of FIG. 2. Therefore, the acceleration of ions in the plasma toward the lower electrode part 10c is reduced compared to when the voltage adjusting part 33 is not provided, and damage caused by ion collision that may be applied to the lower electrode part 10c can also be reduced. The lower electrode part 10c shown in FIGS. 4 and 5 is formed of a single electrode plate 10c1 of a mesh structure.

FIG. 6 illustrates a potential that may occur in the inner region of the plasma supply part 10 shown in FIGS. 4 and 5. FIG. 7 shows the potential of the upper electrode 10a that generates the potential shown in FIG. 6 that may occur in the inner region of the plasma supply part 10. In FIGS. 6 and 7, the potential that can be generated in the inner region of the plasma supply part 10 corresponding to the peak (maximum value) of the RF voltage shown at the point P2a of graph G2b that is applied to the upper electrode 10a is expressed by the broken line K2a of the graph G2a. The potential that can be generated in the inner region of the plasma supply part 10 corresponding to the peak (minimum value) of the RF voltage shown at the point P2b of the graph G2b that is applied to the upper electrode 10a is expressed by the broken line K2b of the graph G2a. In this manner, due to the voltage adjusting part 33 shown in FIGS. 4 and 5, a voltage having a waveform shown in graph G2b in FIG. 7, in which the positive voltage component of the RF voltage outputted from the RF power supply 30 is suppressed, is applied to the upper electrode 10a. Since the positive voltage component of the RF voltage is suppressed, the maximum acceleration voltage MAV corresponding to the sheath voltage of the sheath region MS is suppressed compared to the maximum acceleration voltage MAV shown in the graph G1a of FIG. 2 in the case where the voltage adjusting part 33 is not provided. Therefore, damage caused by ion collision that may be applied to the lower electrode part 10c can also be suppressed.

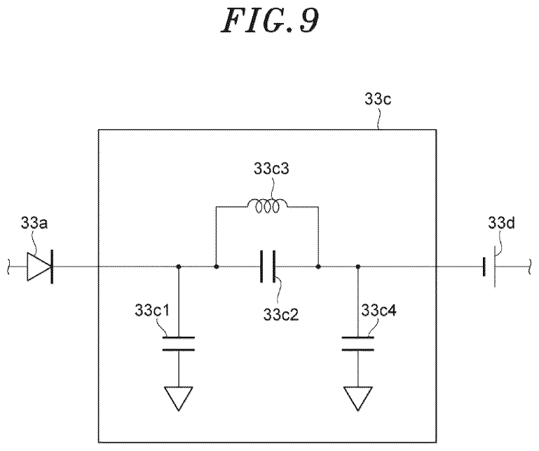

The plasma supply part 10 and the voltage adjusting part 33 of the plasma processing apparatus 100 according to one exemplary embodiment are shown in FIGS. 8 and 9.

The voltage adjusting part 33 shown in FIG. 8 is configured to suppress the positive voltage component of the RF voltage applied to the upper electrode 10a by the RF power supply 30. The voltage adjusting part 33 shown in FIG. 8 includes a diode 33a, a filter circuit 33c, and a DC power supply 33d. The anode of the diode 33a is electrically connected to the upper electrode 10a.

As shown in FIG. 9, the filter circuit 33c includes a capacitor 33c1, a capacitor 33c2, a capacitor 33c4, and an inductor 33c3. The inductor 33c3 and the capacitor 33c2 are electrically connected in parallel between the diode 33a and the DC power supply 33d. The cathode of the diode 33a is electrically connected to the negative terminal of the DC power supply 33d via the inductor 33c3 and the capacitor 33c2. The cathode of the diode 33a is electrically connected to the ground via the capacitor 33c1. The negative terminal of the DC power supply 33d is electrically connected to the ground via the capacitor 33c4. The positive terminal of the DC power supply 33d is electrically connected to the lower electrode part 10c and the ground.

In the plasma processing apparatus 100 including the lower electrode part 10c and the voltage adjusting part 33 shown in FIGS. 8 and 9, the maximum acceleration voltage MAV (sheath voltage of the sheath region MS) shown in the graph G3a of FIG. 10 is lower than the maximum acceleration voltage MAV shown in the graph G1a of FIG. 2. Therefore, the acceleration of ions in the plasma toward the lower electrode part 10c is reduced compared to the case in which the voltage adjusting part 33 is not provided, and damage caused by ion collision that may be applied to the lower electrode part 10c can also be reduced. The lower electrode part 10c shown in FIG. 8 is formed of a single electrode plate 10c1 of a mesh structure.

FIG. 10 illustrates potentials that may occur in the inner region of the plasma supply part 10 shown in FIGS. 8 and 9. FIG. 11 shows the potential of the upper electrode 10a that generates the potential shown in FIG. 10 that may occur in the inner region of the plasma supply part 10. In FIGS. 10 and 11, the potential that may occur in the inner region of the plasma supply part 10 corresponding to the peak (maximum value) of the RF voltage shown at the point P3a of the graph G3b that is applied to the upper electrode 10a is expressed by the broken line K3a of the graph G3a. The potential that may occur in the inner region of the plasma supply part 10 corresponding to the peak (minimum value) of the RF voltage shown at the point P3b of the graph G3b that is applied to the upper electrode 10a is expressed by the broken line K3b of the graph G3a. In this manner, the voltage adjusting part 33 shown in FIGS. 8 and 9 applies a voltage having a waveform of the graph G3b shown in FIG. 11, in which the positive voltage component of the RF voltage outputted from the RF power supply 30 is sufficiently suppressed, to the upper electrode 10a. Therefore, the maximum acceleration voltage MAV corresponding to the sheath voltage of the sheath region MS is suppressed compared to the maximum acceleration voltage MAV shown in the graph G1a of FIG. 2 in the case where the voltage adjusting part 33 is not provided. Hence, damage caused by ion collision that may be applied to the lower electrode part 10c can also be suppressed.

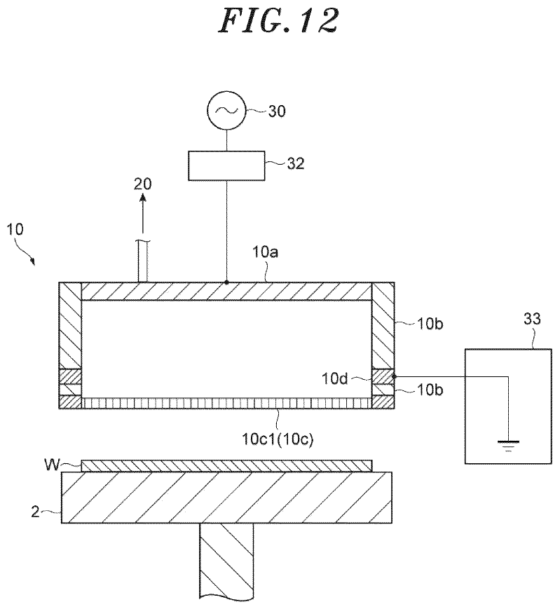

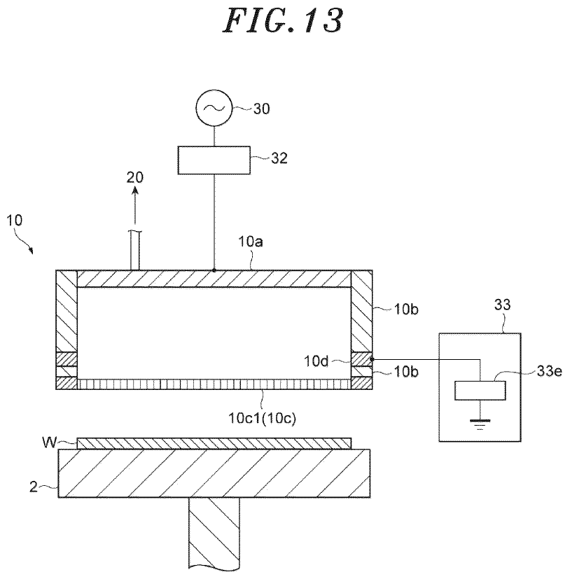

The plasma supply part 10 and the voltage adjusting part 33 of the plasma processing apparatus 100 according to one exemplary embodiment are shown in FIGS. 12 and 13.

The plasma processing apparatus 100 having the plasma supply part 10 shown in FIG. 12 further includes an electrode 10d. The electrode 10d is disposed on a sidewall 10b of the plasma supply part 10 extending between the upper electrode 10a and the lower electrode part 10c. The electrode 10d is electrically connected to the ground (the voltage adjusting part 33). The voltage adjusting part 33 shown in FIG. 12 is configured to electrically connect the electrode 10d to the ground. The lower electrode part 10c shown in FIG. 12 is configured to be in an electrically floating state. In this manner, the lower electrode part 10c is in an electrically floating state. Therefore, the potential of the lower electrode part 10c can change in response to the plasma potential, so that the maximum acceleration voltage MAV corresponding to the sheath voltage is maintained at a low level. Hence, the maximum acceleration voltage MAV corresponding to the sheath voltage in the sheath region MS can be suppressed compared to the maximum acceleration voltage MAV shown in the graph G1a of FIG. 2 in the case where the voltage adjusting part 33 is not provided. Accordingly, damage caused by ion collision that is applied to the lower electrode part 10c can be sufficiently reduced.

The plasma processing apparatus 100 having the plasma supply part 10 shown in FIG. 13 further includes the electrode 10d. The electrode 10d is disposed on the sidewall 10b of the plasma supply part 10 extending between the upper electrode 10a and the lower electrode part 10c. The voltage adjusting part 33 shown in FIG. 13 includes an LC series resonant circuit 33e. The voltage adjusting part 33 is configured to electrically connect the electrode 10d to the ground via the LC series resonant circuit 33e. The electrode 10d is electrically connected to the ground via the LC series resonant circuit 33e. The lower electrode part 10c shown in FIG. 13 is configured to be in an electrically floating state. In this manner, the lower electrode part 10c is in an electrically floating state. Therefore, the potential of the lower electrode part 10c can change in response to the plasma potential, so that the maximum acceleration voltage MAV corresponding to the sheath voltage is maintained at a low level. Hence, the maximum acceleration voltage MAV corresponding to the sheath voltage of the sheath region MS can be suppressed compared to the maximum acceleration voltage MAV shown in the graph Ga of FIG. 2 in the case where the voltage adjusting part 33 is not provided. Accordingly, damage caused by ion collision that is applied to the lower electrode part 10c can also be sufficiently reduced.

In the plasma processing apparatus 100 including the lower electrode part 10c and the voltage adjusting part 33 shown in FIG. 12 or 13, the maximum acceleration voltage MAV shown in the graph G4a of FIG. 14 is lower than the maximum acceleration voltage MAV shown in the graph G1a of FIG. 2. Therefore, the acceleration of ions in the plasma toward the lower electrode part 10c is reduced compared to when the voltage adjusting part 33 is not provided, and damage caused by ion collision that may be applied to the lower electrode part 10c can also be reduced. The lower electrode part 10c shown in FIGS. 12 and 13 is formed of a single electrode plate 10c1 of a mesh structure.

FIG. 14 illustrates potentials that may occur in the inner region of the plasma supply part 10 shown in FIGS. 12 and 13. FIG. 15 shows the potential of the upper electrode 10a that generates the potential shown in FIG. 14 that may occur in the inner region of the plasma supply part 10. In FIGS. 14 and 15, the potential that may occur in the inner region of the plasma supply part 10 corresponding to the peak (maximum value) of the RF voltage shown at the point P4a of the graph G4b that is applied to the upper electrode 10a is expressed by the broken line K4a of the graph G4a. The potential that can be generated in the inner region of the plasma supply part 10 corresponding to the peak (minimum value) of the RF voltage shown at the point P4b that is applied to the upper electrode 10a is expressed by the broken line K4b of the graph G4a. The potential that can be generated in the inner region of the plasma supply part 10 corresponding to the zero value of the RF voltage shown at the point P4c that is applied to the upper electrode 10a is expressed by the broken line K4c of the graph G4a. As shown in the graph G4a of FIG. 14 and the graph G4b of FIG. 15, the lower electrode part 10c shown in FIGS. 12 and 13 is in an electrically floating state, so that the potential of the lower electrode part 10c can change in response to the variation in the plasma potential. Therefore, the maximum acceleration voltage MAV corresponding to the sheath voltage of the sheath region MS is suppressed compared to the maximum acceleration voltage MAV shown in the graph G1a of FIG. 2 in the case where the voltage adjusting part 33 is not provided. Hence, damage caused by ion collision that may be applied to the lower electrode part 10c can also be suppressed.

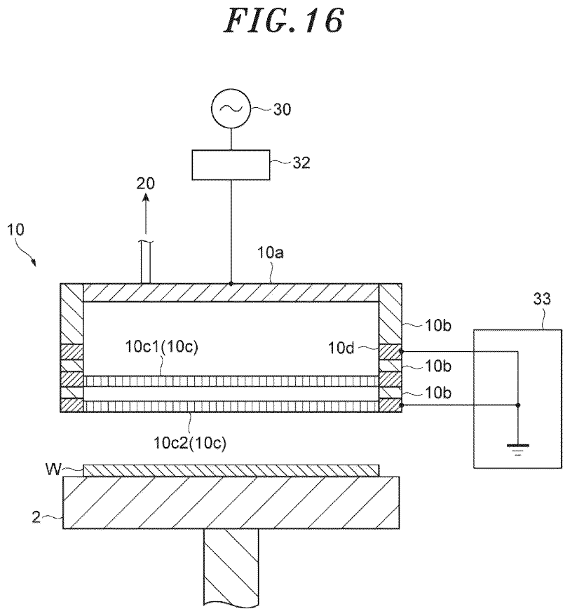

The plasma supply part 10 and the voltage adjusting part 33 of the plasma processing apparatus 100 according to one exemplary embodiment are shown in FIG. 16.

The plasma supply part 10 shown in FIG. 16 further includes an electrode plate 10c2 in addition to the configuration of the plasma supply part 10 shown in FIG. 12. In other words, the lower electrode part 10c includes an electrode plate 10c1 and an electrode plate 10c2, each having a mesh structure, extending parallel to each other. The electrode plate 10c1 is disposed between the upper electrode 10a and the electrode plate 10c2, and is configured to be in an electrically floating state. The electrode plate 10c2 is electrically connected to the ground (voltage adjusting part 33). The voltage adjusting part 33 shown in FIG. 16 is configured to electrically connect the electrode 10d and the electrode plate 10c2 to the ground.

The maximum acceleration voltage MAV (sheath voltage of the sheath region MS) in the plasma processing apparatus 100 including the lower electrode part 10c and the voltage adjusting part 33 shown in FIG. 16 is the same as the maximum acceleration voltage MAV shown in the graph G4a of FIG. 14. Therefore, the acceleration of ions in the plasma toward the lower electrode part 10c is reduced compared to when the voltage adjusting part 33 is not provided, and damage caused by ion collision that may be applied to the lower electrode part 10c can also be reduced. In other words, the configuration of FIG. 16 can achieve the same effect as that achieved by at least the configuration of FIG. 12. Further, since the electrode plate 10c2 is provided in the configuration of FIG. 16, when ions in the plasma leak from the electrode plate 10c1, charge exchange can be performed between the ions and the electrode plate 10c2 connected to the ground. Accordingly, the energy of ions in the plasma that leak to the outer region of the plasma supply part 10 can be further reduced. In some cases, the ions in the plasma of which energy has been reduced may leak to the outer region of the plasma supply part 10 and collide with the substrate W and the wall surface of the processing chamber 1. In this case, since the energy of ions has been reduced, the damage to the substrate W or the particle generation in the processing chamber 1 due to ion bombardment can be suppressed.

While various exemplary embodiments have been described above, various additions, omissions, substitutions, and modifications may be made without being limited to the exemplary embodiments described above. Further, elements from different embodiments can be combined to form other embodiments.

From the above description, it will be appreciated that various embodiments of the present disclosure have been described herein for purposes of illustration, and that various changes can be made without departing from the scope and spirit of the present disclosure. Therefore, the various embodiments disclosed herein are not intended to be limiting, with a true scope and spirit being indicated by the appended claims.

1. A plasma processing apparatus comprising:
a processing chamber;
a radio-frequency (RF) power supply;
a plasma supply part including an upper electrode and a lower electrode part and configured to supply only radicals, or radicals and some ions, to the processing chamber, the upper electrode being electrically connected to the RF power supply and to which an RF voltage from the RF power supply is applied, and the lower electrode part being disposed to face the upper electrode;
a gas supply part configured to supply to the plasma supply part a processing gas used for plasma generation in the plasma supply part; and
a voltage adjusting part used for adjusting a voltage of the upper electrode,
wherein the gas supply part supplies the processing gas to a space provided by the upper electrode and the lower electrode part,
the lower electrode part includes an electrode plate having a mesh structure that extends along a surface of the upper electrode and configured to allow communication between an inner region and an outer region of the plasma supply part provided by the lower electrode part, and
the plasma supply part and the voltage adjusting part are configured to lower a sheath voltage of a sheath region formed on the lower electrode part during plasma generation in the plasma supply part.

2. The plasma processing apparatus of claim 1, wherein the voltage adjusting part includes a diode,
an anode of the diode is electrically connected to the upper electrode, and
a cathode of the diode is electrically connected to ground together with the lower electrode part.

3. The plasma processing apparatus of claim 1, wherein the voltage adjusting part includes a switch circuit,
the lower electrode part is electrically connected to ground, and
the switch circuit is electrically connected between the lower electrode part and the upper electrode, and is configured to suppress a positive voltage component of an RF voltage applied to the upper electrode by the RF power supply.

4. The plasma processing apparatus of claim 1, wherein the voltage adjusting part includes a diode, a filter circuit, and a DC power supply,
an anode of the diode is electrically connected to the upper electrode,
the filter circuit includes a first capacitor, a second capacitor, a third capacitor, and an inductor,
the inductor and the second capacitor are electrically connected in parallel between the diode and the DC power supply,
a cathode of the diode is electrically connected to a negative terminal of the DC power supply via the inductor and the second capacitor,
the cathode of the diode is electrically connected to ground via the first capacitor,
the negative terminal of the DC power supply is electrically connected to the ground via the third capacitor, and
a positive terminal of the DC power supply is electrically connected to the lower electrode part and the ground.

5. The plasma processing apparatus of claim 1, further comprising:
an electrode disposed on a sidewall of the plasma supply part extending between the upper electrode and the lower electrode part and electrically connected to ground,
wherein the voltage adjusting part is configured to electrically connect the electrode to the ground, and
the lower electrode part is configured to be in an electrically floating state.

6. The plasma processing apparatus of claim 1, further comprising:
an electrode disposed on a sidewall of the plasma supply part extending between the upper electrode and the lower electrode part and electrically connected to ground via an LC series resonant circuit,
wherein the lower electrode part is configured to be in an electrically floating state.

7. The plasma processing apparatus of claim 1, further comprising:
an electrode disposed on a sidewall of a plasma supply part extending between the upper electrode and the lower electrode part and electrically connected to ground,
wherein the lower electrode part includes a first electrode plate and a second electrode plate, each having a mesh structure, extending parallel to each other,
the first electrode plate is disposed between the second electrode plate and the upper electrode and configured to be in an electrically floating state,
the second electrode plate is electrically connected to the ground, and
the voltage adjusting part is configured to electrically connect the electrode and the second electrode plate to the ground.
